(19) United States
(12) Patent Application Publication
(10) Pub. No.: US 2021/0257597 A1
(43) Pub. Date: Aug. 19, 2021

(54) INTERNAL LIGHT EXTRACTION LAYERS CURED BY NEAR INFRARED RADIATION

(71) Applicant: CORNING INCORPORATED, CORNING, NY (US)

(72) Inventors: Ssu-Wei Hu, Chutung (TW); Jen-Chieh Lin, Horseheads, NY (US)

(21) Appl. No.: 17/251,462

(22) PCT Filed: Jun. 11, 2019
(86) PCT No.: PCT/US2019/036501

§ 371 Date: Dec. 11, 2020

Related U.S. Application Data
(60) Provisional application No. 62/687,948, filed on Jun. 21, 2018.

(51) Int. Cl. H01L 51/56; H01L 51/52

(52) U.S. Cl. CPC H01L 51/56; H01L 51/5268

(57) ABSTRACT

A process for forming an article for improved light extraction includes: providing abase substrate; disposing a precursor on the base substrate, the precursor having: particles having an average diameter in a range of 10 nm to 1 μm and including an inorganic oxide and an organic binder; exposing the precursor to a first radiation having a peak emission wavelength in a range of 500 nm to 2000 nm for a time in a range of 1 second to 300 seconds to form a porous light extraction layer having an average pore diameter in a range of 10 nm to 1000 nm, such that the porous light extraction layer improves light output of the article by a factor of 1.7× or greater.

This application claims the benefit of priority under 35 U.S.C. § 119 of U.S. Provisional Application Ser. No. 62/687,948 filed on Jun. 21, 2018 the content of which is relied upon and incorporated herein by reference in its entirety.

### BACKGROUND

### 1. Field

This disclosure relates to internal light extraction layers cured by near infrared radiation (NIR).

### 2. Technical Background

An organic light emitting diode (OLED) is a light-emitting element that generates light using energy emitted from excitations created by the recombination of electrons injected through a cathode and holes injected through an anode. OLEDs have a variety of advantages, such as low-voltage driving, self-emission, a wide viewing angle, high resolution, natural color reproducibility, and short response times. OLED lighting is also advantageous because it is a diffusive light source that minimizes glare. OLEDs generate less heat as compared with a traditional light emitting diodes (LEDs), which saves power and material usage.

One challenge for OLED lighting is light efficiency loss, generally caused by a difference of refractive index between layers that results in light scattering or reflection within the device, or by light absorption within a layer. To improve the efficiency, one or more light extraction substrates may be used in an OLED device. Conventional methods for forming light extraction substrates require thermal treatments at temperatures up to 500° C. for a duration lasting 15 to 30 minutes or more for each individual layer of the substrate. This process is time consuming, increases manufacturing costs, and the high thermal treatment temperatures are unsuitable for some substrate materials.

The present application discloses improved internal light extraction layers cured by near infrared radiation (NIR) that reduces treatment temperature and time.

### SUMMARY

In some embodiments, a process for forming an article for improved light extraction comprises: providing a base substrate; disposing a precursor on the base substrate, the precursor comprising: particles having an average diameter in a range of 10 nm to 1 μm and comprising an inorganic oxide and an organic binder; exposing the precursor to a first radiation having a peak emission wavelength in a range of 500 nm to 2000 nm for a time in a range of 1 second to 300 seconds to form a porous light extraction layer having an average pore diameter in a range of 10 nm to 1000 nm, wherein the porous light extraction layer improves light output of the article by a factor of 1.7× or greater.

In one aspect, which is combinable with any of the other aspects or embodiments, the step of exposing is for a time in a range of 10 seconds to 60 seconds.

In one aspect, which is combinable with any of the other aspects or embodiments, the inorganic oxide comprises a first inorganic material of titanium dioxide (TiO₂) and a second inorganic material including at least one of silicon dioxide (SiO₂), zinc oxide (ZnO), tin dioxide (SnO₂), or combinations thereof.

In one aspect, which is combinable with any of the other aspects or embodiments, the inorganic oxide comprises titanium dioxide (TiO₂).

In one aspect, which is combinable with any of the other aspects or embodiments, the organic binder comprises at least one of polyethylene glycol, polyethylene oxide, polyvinyl alcohol, polyvinylpyrrolidone, polyacryclic acid, or combinations thereof.

In one aspect, which is combinable with any of the other aspects or embodiments, the first radiation has a power in a range of 0.1 W/cm² to 1000 W/cm².

In one aspect, which is combinable with any of the other aspects or embodiments, the first radiation is operated at a power output of less than 100%.

In one aspect, which is combinable with any of the other aspects or embodiments, the first radiation is generated from a pulsed or steady-state radiation source comprising a metallic filament, wherein the metallic filament comprises at least one of a tungsten filament, a nickel-chromium (NiCr) filament, an iron-chromium-aluminum (FeCrAl) filament, or a combination thereof.

In one aspect, which is combinable with any of the other aspects or embodiments, the process further comprises: coating the porous light extraction layer with an inorganic polymer layer.

In one aspect, which is combinable with any of the other aspects or embodiments, the process further comprises: exposing the inorganic polymer layer to a second radiation to form a porous light extraction layer stack.

In one aspect, which is combinable with any of the other aspects or embodiments, the step of exposing the inorganic polymer layer comprises the second radiation having a peak emission wavelength in a range of 500 nm to 2000 nm for a time in a range of 1 second to 300 seconds.

In one aspect, which is combinable with any of the other aspects or embodiments, the step of exposing the inorganic polymer layer is for a time in a range of 10 seconds to 60 seconds.

In one aspect, which is combinable with any of the other aspects or embodiments, the process further comprises: thermally sintering the inorganic polymer layer to form a porous light extraction layer stack.

In one aspect, which is combinable with any of the other aspects or embodiments, the inorganic polymer layer comprises siloxane-based molecules.

In one aspect, which is combinable with any of the other aspects or embodiments, the inorganic polymer is a planarizing layer on the porous light extraction layer.

In one aspect, which is combinable with any of the other aspects or embodiments, the inorganic polymer layer is a thickness in a range of 0.01 μm to 1 μm.

In one aspect, which is combinable with any of the other aspects or embodiments, the base substrate comprises a continuous, flexible sheet, and the process comprises a roll-to-roll process.

In one aspect, which is combinable with any of the other aspects or embodiments, the continuous, flexible sheet comprises a glass sheet with a thickness of 100 μm or less.

In one aspect, which is combinable with any of the other aspects or embodiments, a maximum temperature of the porous light extraction layer during the step of exposing is 250° C. or less.

In one aspect, which is combinable with any of the other aspects or embodiments, the process further comprises: forming at least one transparent electrode layer and an organic light emitting diode layer on the porous light extraction layer stack.

In some embodiments, a process for forming an article for improved light extraction comprises: providing a base substrate; disposing a precursor on the base substrate, the precursor comprising: particles having an average diameter in a range of 10 nm to 1 μm and comprising an inorganic oxide and an organic binder; coating the precursor with an inorganic polymer layer to form a stack; exposing the stack to radiation having a peak emission wavelength in a range of 500 nm to 2000 nm for a time in a range of 1 second to 300 seconds to form a porous light extraction layer stack comprising a porous light extraction layer, wherein the porous light extraction layer has an average pore diameter in a range of 10 nm to 1000 nm and improves light output of the article by a factor of 1.7× or greater.

In some embodiments, an article for improved light extraction comprises: a base substrate; a porous light extraction layer having an average pore diameter in a range of 10 nm to 1000 nm, wherein the porous light extraction layer improves light output of the article by a factor of 1.7× or greater.

In one aspect, which is combinable with any of the other aspects or embodiments, the porous light extraction layer comprises a laser-treated porous light extraction layer having an inorganic oxide material and an organic binder.

In one aspect, which is combinable with any of the other aspects or embodiments, the inorganic binder comprises at least one of titanium dioxide (TiO₂), silicon dioxide (SiO₂), zinc oxide (ZnO), tin dioxide (SnO₂), or combinations thereof.

In one aspect, which is combinable with any of the other aspects or embodiments, the organic binder comprises at least one of polyethylene glycol, polyethylene oxide, polyvinyl alcohol, polyvinylpyrrolidone, polyacryclic acid, or combination thereof.

In one aspect, which is combinable with any of the other aspects or embodiments, the porous light extraction layer has a CIE L*a*b* color space coordinate range of between 120 and 125.

In some embodiments, an organic light emitting diode device comprises a porous light extraction layer formed by a process described herein.

### BRIEF DESCRIPTION OF THE DRAWINGS

The disclosure will become more fully understood from the following detailed description, taken in conjunction with the accompanying figures, in which:

FIG. 1 illustrates a light extraction substrate and an OLED, according to some embodiments.

FIG. 2 illustrates a process for NIR treatment, according to some embodiments.

FIG. 3 illustrates a process for NIR treatment, according to some embodiments.

FIG. 4 illustrates a schematic of the two-stage pulse function of a radiation source used, according to some embodiments.

FIG. 5 illustrates a system for radiation treatment, according to some embodiments.

FIG. 6 illustrates thermal gravimetric analysis (TGA) of titanium dioxide (TiO₂) treated with NIR radiation for various processing times, according to some embodiments.

### DETAILED DESCRIPTION

Reference will now be made in detail to exemplary embodiments which are illustrated in the accompanying drawings. Whenever possible, the same reference numerals will be used throughout the drawings to refer to the same or like parts. The components in the drawings are not necessarily to scale, emphasis instead being placed upon illustrating the principles of the exemplary embodiments. It should be understood that the present application is not limited to the details or methodology set forth in the description or illustrated in the figures. It should also be understood that the terminology is for the purpose of description only and should not be regarded as limiting.

Additionally, any examples set forth in this specification are illustrative, but not limiting, and merely set forth some of the many possible embodiments of the claimed invention. Other suitable modifications and adaptations of the variety of conditions and parameters normally encountered in the field, and which would be apparent to those skilled in the art, are within the spirit and scope of the disclosure.

The present disclosure relates to processes for making light extraction substrates for an organic light emitting diode (OLED) and products including such light extraction substrates. More specifically, the present application discloses improved processing conditions using near infrared radiation (NIR) for forming internal light extraction layers that reduce thermal treatment temperatures and time requirements during the curing stage.

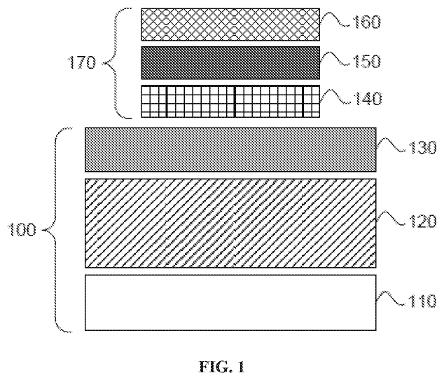

FIG. 1 illustrates an example of a light extraction substrate 100, according to an embodiment. It will be understood by those of skill in the art that the processes described herein can be applied to other configurations of light extraction substrates.

In some embodiments, light extraction substrate 100 can include a base substrate 110 and a light extraction layer 120 disposed on the base substrate 110. In some embodiments, light extraction substrate 100 can include a planarization layer 130. In some embodiments, planarization layer 130 can be disposed directly adjacent to light extraction layer 120. As used here, “directly adjacent” means that at least a portion of two components are in direct physical contact with each other. Other layers can be disposed on, between, or adjacent to base substrate 110, light extraction layer 120, and/or planarization layer 130. Additionally, layers can exist on a single surface of base substrate 110 as shown in FIG. 1, or substrate 110 can have layers existing on both surfaces. These additional layers can be organic or inorganic materials. These layers applied to the surfaces of base substrate 110 do not need to be continuous across the entire surface. They can also be patterned or selectively located.

The base substrate 110 comprises a first, roughly planar surface, a second roughly planar surface and at least one edge. In general, the first and second roughly planar surfaces are parallel to each other. Base substrate 110 can serve as a foundation upon which to build light extraction substrate 100 and can provide support to light extraction layer 120, planarization layer 130, and any other layer disposed thereon. In addition, base substrate 110 can serve as an encapsulation layer that is disposed on a path along which light generated by an OLED is emitted to allow the generated light to exit therethrough while protecting the OLED from the external environment.

Any transparent substrate that has suitable light transmittance and mechanical properties can be used as the base substrate 110, including glasses, glass ceramics, organic polymeric materials, and ceramics. For example, in some embodiments, the base substrate 110 may be formed from a polymeric material, for example, a heat or ultraviolet (UV) curable organic film. In some embodiments, a chemically strengthened glass substrate formed from, for example, soda-lime glass (SiO₂—CaO—Na₂O) or aluminosilicate glass (SiO₂—Al₂O₃—Na₂O)) may be used as the base substrate 110. In some embodiments, a substrate formed from a metal oxide or a metal nitride may be used as the base substrate 110. A flexible substrate, for example, a thin glass substrate having a thickness of 1.5 mm or less can be used as the base substrate 110. As an example, the substrate can have a thickness of 0.5 mm, 0.4 mm, 0.3 mm, 0.2 mm, 0.1 mm, or 0.05 mm or any value in between. Additionally, the base substrate 110 can be made of multiple planar layers of similar or different materials.

In a typical OLED without a light extraction layer, only about 20% of the light generated by the organic light emitting layer(s) is emitted from the device. The remainder of the light is either absorbed or reflected. A light extraction layer, such as light extraction layer 120, can scatter light generated by an OLED. This scattering can change the direction of photons, so that a photon that would have been absorbed or reflected in the absence of a light extraction layer is instead emitted, thereby improving light extraction efficiency of the OLED device. This scattering can be caused, for example, by light extraction layer 120 having a rough interface, or by particles, interfaces, or pores within light extraction layer 120.

Aspects described herein improve the light output by a factor of 1.2, 1.5, 1.7, 2.0 or greater.

In some embodiments, light extraction layer 120 can be formed on the base substrate 110. In an embodiment, when the light extraction substrate 100 is coupled with an OLED 170, the light extraction layer 120 is disposed between the OLED 170 and the base substrate 110. In such an embodiment, the light pathway is first through the light extraction layer 120 and then through the base substrate 110. In addition, the light extraction layer or OLED may be formed on a substrate that already has additional materials or patterned features on it.

In some embodiments, light extraction layer 120 comprises an inorganic oxide, metal oxide, or metalloid oxide. In some embodiments, the light extraction layer 120 can comprise an inorganic oxide, metal oxide, or metalloid oxide having a refractive index of from 1.2 to 2.0. In some embodiments, the light extraction layer 120 has a refractive index of 1.2, 1.3, 1.4, 1.5, 1.6, 1.7, 1.8, 1.9, or 2.0, or any range in between these values. In some embodiments, the light extraction layer has a refractive index that is within +0.7, +0.6, +0.5, +0.4, +0.3, +0.25, +0.2, +0.15, +0.1, or ±0.05, of the refractive index of the substrate. In some embodiments, the light extraction layer has a refractive index that is within AAA of the refractive index of the planarizing layer 130. In some embodiments, the light extraction layer has a refractive index that is within ±0.7, ±0.6, ±0.5, ±0.4, ±0.3, ±0.25, ±0.2, ±0.15, ±0.1, or ±0.05, of the refractive index of the first electrode 140 or the OLED 170.

The oxide material may be in the form of particles, such as nano- or microparticles. For example, the particles may have an average diameter along their longest axis of from 10 nm to 1 μm as measured using standard techniques (for example, laser diffraction, dynamic light scattering, or image analysis). For example, light extraction layer 120 can comprise TiO₂ (i.e. titania). In some embodiments, the TiO₂ is in the form of rutile, or in a tetragonal crystal symmetry. In some embodiments, light extraction layer 120 comprises a porous TiO₂ layer. For example, light extraction layer 120 can have pores with a diameter of 10 nm to 1000 nm. In some embodiments, light extraction layer 120 comprises rutile TiO₂, having an index of refraction of n˜2.6.

A thickness of the light extraction layer 120 can range from 0.4 μm to 5 μm. In some embodiments, light extraction layer 120 can have a thickness of 0.5 μm to 2 μm. In some embodiments, light extraction layer 120 can have a thickness of 0.8 μm to 1.7 μm. In some embodiments, one or more metal oxides, such as SiO₂, TiO₂, ZnO, SnO₂, or combinations thereof can be used for light extraction layer 120. Other inorganic and/or organic materials can also be used.

In some embodiments, planarization layer 130 can be disposed on light extraction layer 120. In some embodiments, the planarization layer 130 can also be disposed directly adjacent to an OLED 170, and more particularly, the anode (e.g., 140) of the OLED 170. Because the planarization layer 130 can abut the anode of the OLED 170, the surface of the planarization layer 130 should have a high degree of flatness, as measured by atomic force microscopy, to prevent the electrical characteristics of the OLED 170 from being degraded. Thus, the planarization layer 130 should have a thickness sufficient to smooth out surface roughness of the light extraction layer 120. In some embodiments, a thickness of the planarization layer 130 can range from 0.1 μm to 5 μm. In some embodiments, a thickness of the planarization layer 130 can range from 0.5 μm to 1 μm. In some embodiments, the thickness of the planarization layer 130 can be 0.7 μm.

The planarization layer 130 can be formed from an organic material, an inorganic material, or a hybrid material of organic and inorganic materials. In some embodiments, the planarization layer comprises multiple layers of the same or different materials. In some embodiments, a siloxane, for example, PDMS (polydimethylsiloxane) having a refractive index n of from 1.3 to 1.5, may be used. In some embodiments, the planarization layer 130 can be formed from a metal oxide, such as MgO, Al₂O₃, ZrO₂, SnO₂, ZnO, SiO₂ or TiO₂, or combinations thereof.

In some embodiments, the light extraction substrate 100 further comprises an external light extraction layer or other material layer on surface of the base substrate 110 distal or opposite to the light extraction layer 120. This layer on the opposite side of the substrate can be patterned or continuous. Such an external light extraction layer may comprise a film, particles, or modifications to the base substrate 110. Examples of external light extraction layers include an etched surface on the base substrate 110, a nanoparticle coating of high index particles optionally in a low index matrix or a matrix index matched to the base substrate 110, a polymer film comprising light extraction features, etc.

As also shown in FIG. 1, in some embodiments, an OLED 170 can be disposed on light extraction substrate 100. In some embodiments, OLED 170 can be disposed on planarization layer 130. OLED 170 could also be disposed on light extraction layer 120. In some embodiments a plurality of OLEDs can be disposed on light extraction substrate 100. These can be disposed horizontally in relation to each other or vertically.

OLEDs are well-known in the art, and any appropriate OLED structure may be used. For example, OLED 170 can include a first electrode 140 and a second electrode 160. First electrode 140 can be the anode and second electrode 160 can be the cathode, or vice versa. In some embodiments, first electrode 140 can be transparent, and can be made of indium tin oxide (ITO) or other transparent electrode materials. Second electrode 160 can be transparent or reflective, such as a gold, silver, copper, or aluminum layer.

Organic layer 150 can be disposed between first electrode 140 and second electrode 160. When a voltage is applied between first electrode 140 and second electrode 160, organic layer 150 emits light. Organic layer 150 can include a plurality of sub-layers, and a subset of those sub-layers may emit light.

As discussed above, light extraction substrates are typically formed by a thermal process using an oven. By way of example, Table 1 below shows an example of typical thermal process requirements for layers of a light extraction substrate.

TABLE 1

| | | Wet | Drying | Sintering | |
|---|---|---|---|---|---|
| | | thick- | Temp | Temp | |
| | Mate- | ness | (° C.)/ | (° C.)/ | |
| Layer | rials | (μm) | sec | min | Requirement |
| 1 | SiO₂ in | 8 | 150° C./ | 500° C./ | Haze: 60-80% |
| | TiO₂ | | 30 sec | 30 min | T(%): 60-80% |
| | | | | | (haze meter) |
| | | | | | Variation <10% |
| 2 | TiO₂ | 9 | 150° C./ | 200° C./ | Thickness: ~0.8 um |
| | | | 30 sec | 30 min | Variation <10% |
| 3 | Siloxane | 13.5 | 120° C./ | 230° C./ | Thickness: ~1 um |
| | | | 30 sec | 5 min | Roughness <100 nm |
| | | | | | Variation <10% |

In the example shown in Table 1, Layer 1 can include SiO₂ particles (silica) in a TiO₂ matrix, Layer 2 can be a layer of TiO₂, and Layer 3 can be an organic or inorganic planarization layer (e.g. a siloxane). All three layers have absorption in UV range. With this high index matrix and the index difference between SiO₂ and TiO₂, more light can be scattered and extracted by the light extraction substrate. To make these stack layers, three coating solutions can be applied on a glass substrate (e.g., 0.1 mm Corning® Willow® Glass or 0.5-0.7 mm Corning® EAGLE® Glass), first by a slot-die coating process followed by drying and thermal process steps. As discussed above, some embodiments of the light extraction substrates disclosed herein include only the equivalent of Layer 2 (a light extraction layer) and Layer 3 (a planarization layer). The layers applied to base substrate 110 can be formed in continuous roll-to-roll processing or can be formed using processes optimized for discrete sheets. In addition to slot-die coating, alternative solution-based coating and printing processes that produce continuous or patterned films can be used. The multiple layers applied to base substrate 110 do not need to be formed using the same process.

As shown in Table 1, a typical thermal treatment process for Layer 1 and Layer 2 requires approximately 30 minutes for each layer using an oven. For Layer 1, the required treatment temperature is approximately 500° C. These treatment times and temperatures are not favorable for manufacturing and power consumption.

The present disclosure describes near infrared radiation (NIR) processes that significantly reduce total process time, and therefore manufacturing costs, for forming OLED light extraction substrates and the like. The NIR processes disclosed herein can shorten the sintering duration to 300 seconds or less at temperatures of approximately 250° C. or less. These processes can be applied, for example, to make the light extraction substrates 100 discussed above.

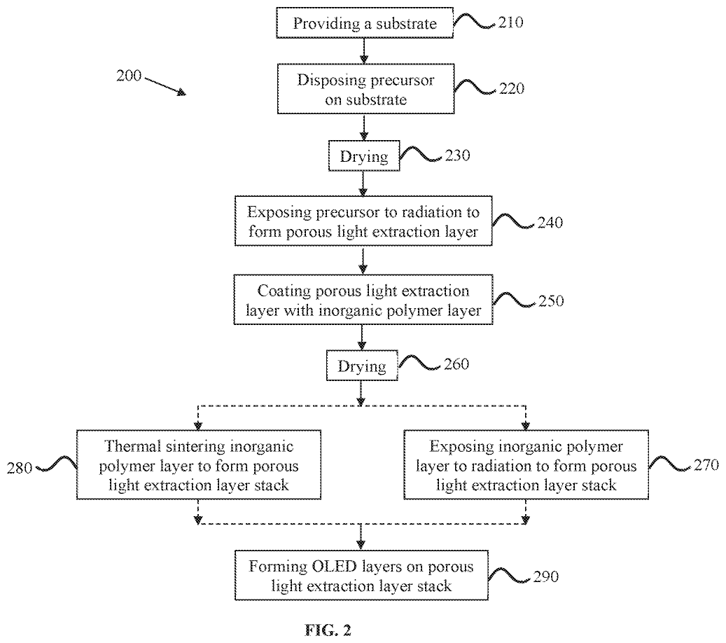

FIG. 2 illustrates a process 200 for NIR treatment, according to some embodiments. In a first step 210 of process 200, a substrate is provided and thereafter, in a second step 220, a precursor is disposed atop the substrate. In some examples, the thickness of the as-deposited precursor layer may be in a range of 5 μm to 20 μm (e.g., 7 μm, 8 μm, 9 μm, 10 μm, or intervening therein). The precursor may comprise particles of a first material comprising an inorganic oxide (i.e., having an average diameter in a range of 10 nm to 1 μm) and an organic binder. The inorganic oxide may comprise a high refractive index, porous matrix such that the difference in indices between the inorganic oxide (e.g., titanium dioxide, TiO₂) and the base substrate (e.g., glass-based) leads to more light being scattered and extracted from the operating device. In some embodiments, the inorganic oxide comprises TiO₂. In some embodiments, the inorganic oxide comprises a first inorganic material of TiO₂ and a second inorganic material including at least one of silicon dioxide (SiO₂), zinc oxide (ZnO), tin dioxide (SnO₂), or combinations thereof. In some embodiments, the inorganic oxide comprises at least one of TiO₂, SiO₂, ZnO, SnO₂, or combinations thereof. In some examples, the precursor may comprise at least one of an inorganic oxide, metal oxide, or metalloid oxide.

The inorganic particles may be in the form of particles, such as nano- or microparticles. For example, the particles may have an average diameter along their longest axis of from 10 nm to 1 μm as measured using standard techniques (e.g., laser diffraction, dynamic light scattering, image analysis, etc.). In examples where the precursor is TiO₂, the titania may be present as rutile (i.e., a tetragonal crystal symmetry) having an index of refraction of n about 2.6.

The organic binder may comprise any known or unknown organic, optionally polymeric, binder material that works with the present system. The organic binder may include at least one of polyethylene glycol, polyethylene oxide, polyvinyl alcohol, polyvinylpyrrolidone, polyacryclic acid, or combinations thereof. In some examples, the adhesion characteristics of the organic binder may be activated, modified or improved after exposure to radiation (step 240). The precursor may further comprise at least one solvent (e.g., water, ethanol, methanol, etc.) which is at least partially removed during drying (step 230) or radiation exposure (step 240).

In step 230 of process 200, the precursor is dried. In some examples, the drying is conducted at a temperature in a range of 50° C. to 250° C. or in a range of 100° C. to 200° C. (e.g., 120° C.) or in a range of 125° C. to 175° C. (e.g., 150° C.). In some examples, the drying is conducted for a duration in a range of 5 seconds to 10 minutes or in a range of 15 seconds to 5 minutes or in a range of 30 seconds to 1 minute. In some examples, the drying is conducted for a duration in a range of 15 seconds to 45 seconds (e.g., 30 seconds). In some examples, the drying is conducted at a temperature of about 120° C. for a duration of about 30 seconds. In some examples, the drying is conducted at a temperature of about 150° C. for a duration of about 30 seconds.

In step 240 of process 200, the dried precursor is exposed to radiation having a peak emission wavelength in a range of 500 nm to 2000 nm to form a porous light extraction layer having an average pore diameter in a range of 10 nm to 1000 nm. Microscopy techniques may be used to determine pore size diameters (e.g., transmission electron microscopy (TEM), scanning electron microscopy (SEM), etc.). In some examples, the exposing may be conducted for a duration in a range of 1 second to 300 seconds, or 10 seconds to 120 seconds, or 10 seconds to 60 seconds (e.g., 45 seconds). In some examples, a maximum temperature of the porous light extraction layer during the exposure of step 240 is 250° C. or less or 200° C. or less or 150° C. or less. The resulting porous light extraction layer may improve light output of an article incorporating the porous light extraction layer by a factor of at least 1.2, or at least 1.5, or at least 1.7, or at least 2.0.

The radiation to which the precursor is exposed may be a continuous emission radiation source having a power in a range of 0.1 W/cm² to 1000 W/cm² (e.g., 50 W/cm²). In some examples, the radiation is generated from a pulsed or steady-state radiation source comprising a metallic filament (e.g., at least one of a tungsten filament, a nickel-chromium (NiCr) filament, an iron-chromium-aluminum (FeCrAl) filament, or combinations thereof).

In some embodiments, the radiation source comprises a pulsed radiation source having a pulse width (when measured at ⅓ peak value) in a range of 1 μs to 100 ms. Other characteristics of the radiation in some examples may include an energy per pulse in a range of 1 J to 5000 J; an energy per pulse delivery (i.e., energy flux) to the material in a range of 0.01 J/cm²/pulse to 1 J/cm²/pulse; and a total energy delivered to the material in a range of 0.1 J/cm² to 100 J/cm².

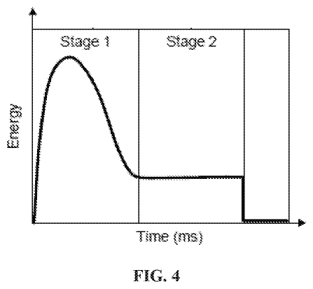

In some examples, pulses from the pulsed radiation source comprise at least a first stage, having an initial part of the pulse, and a second stage, having a subsequent part of the pulse, wherein each stage comprises a pulse energy and pulse duration. FIG. 4 illustrates a schematic of the two-stage pulse function of a radiation source used according to some embodiments. A multi-stage pulse can be particularly designed to provide optimal radiation treatment of the precursor without damaging or heating the substrate or precursor to unacceptable levels. In some examples, the multi-stage pulse comprises a first stage that is higher in energy than the second stage. Alternatively, in some examples, the second stage may be higher in energy than the first stage. The first and second stages may comprise any number of pulse shapes, such as Gaussian, step-function, decaying-function, etc. In the case where there are greater than two stages, any permutation of energy variations may be acceptable in order to obtain the desired product using the embodied processes.

According to some embodiments, the first stage may have an energy/pulse in a range of 100 J/pulse to 5000 J/pulse and a duration in a range of 0.1 ms to 10 ms (e.g., 100 μs to 300 μs). In some implementations, the second stage may, independently, have an energy/pulse in a range of 100 J/pulse to 5000 J/pulse and a duration in a range of 0.1 ms to 10 ms (e.g., 1000 μs to 3000 μs). In some examples, the highest energy stage may have a duration in a range of 0.1 ms to 10 ms, or in a range of 50 μs to 500 μs, or in a range of 50 μs to 100 μs and an energy per pulse in a range of 10 J/pulse to 5000 J/pulse, or in a range of 100 J/pulse to 2500 J/pulse or any value therein. In some examples, the lower energy stages may have a duration in a range of 0.1 ms to 10 ms, or in a range of 1 ms to 10 ms, or in a range of 1 ms to 5 ms, or in a range of 0.1 ms to 5 ms.

Moreover, the first stage may have a total energy delivered to the material in a range of 0.1 J/cm² to 100 J/cm², whereby a ratio of the total energy delivered to the material in the first stage and the total energy delivered to the material in the second stage is in a range of 1 to 4. In some examples, where the stages have different energy values, the ratio of the highest energy of the highest energy stage to the highest energy of lowest energy stage may be in a range of 1.2 to 12, or in a range of 1.5 to 10, or in a range of 5 to 10, or in a range of 2 to 8. In some examples, the first stage has a peak energy in a range of 1.5 times to 10 times higher than a peak energy of the second stage.

In some implementations, the multi-stage pulse further comprises a starter pulse, comprising a short duration, high-energy light pulse prior to the multi-stage pulse. In embodiments comprising a starter pulse, the energy/pulse of the starter pulse is in a range of 2× to 10× greater than the energy/pulse of the highest pulse energy of the multi-stage pulse. For example, the starter pulse has an energy/pulse in a range of 2 times to 10 times greater than the energy/pulse value of the first stage pulse. Additionally, the pulse energy of the starter pulse is in a range of 20 J/pulse to 10,000 J/pulse, or in a range of 100 J/pulse to 5000 J/pulse, or in a range of 200 J/pulse to 2000 J/pulse, or any value therein. The starter pulse may have a duration in a range of 1 μs to 1 ms, or in a range of 10 μs to 1 ms, or in a range of 50 μs to 500 μs, or in a range of 10 μs to 100 μs, or any value therein. Additionally, there may be a delay between the starter pulse and the multi-stage pulse in a range of 0.01 ms to 100 ms, or in a range of 0.1 ms to 50 ms, or in a range of 1 ms to 10 ms, or in a range of 1 ms to 5 ms, or in a range of 0.1 ms to 5 ms.

The porous light extraction layer may have a L*a*b* color space coordinate range of between 120 and 125. Defined by the Commission Internationale de l'Eclairage (CIE), the L*a*b* color space mathematically expresses color as three numerical coordinates: L*, as a lightness coordinate, a*, as a red/green coordinate, and b*, as a yellow/blue coordinate.

The lightness value, L*, ranges between 0 (representing the darkest black) and 100 (representing the brightest white). In theory, there is no maximum values of a* and b*, however in practice, each may vary from −128 to +127 (where for a*, −128 represents absolute green and +127 represents absolute red and for b*, −128 represents absolute blue and +127 represents absolute yellow).

In step 250 of process 200, the porous light extraction layer is coated with an inorganic polymer layer to form a planarizing second layer. In some examples, the coating may be conducted using a slot-die coating process to achieve a relatively uniform flatness profile of the substrate-porous light extraction layer-inorganic polymer layer stack. In slot-die processes, the coating is applied layer-by-layer following by drying (step 260) and curing step(s) (steps 270 and 280) for each layer until a final desired thickness is reached. Alternatively, the coating may be applied as a single layer followed by drying and curing for that single layer.

In some examples, the thickness of the as-deposited inorganic polymer layer may be in a range of 5 μm to 20 μm (e.g., 10 μm, 11 μm, 12 μm, 13 μm, 14 μm, or intervening therein). In some examples, the inorganic polymer may be a siloxane-based polymer comprising at least one of linear siloxane polymers (—SiRR′O—) (with various alkyl and aryl R and R′ side groups), sesquisiloxane polymers (e.g., having ladder structures), siloxane-silarylene polymers (—Si(CH₃)₂OSi(CH₃)₂(C₆H₄)ₘ—) (where the phenylenes are either meta or para and m is an integer), silalkylene polymers (—Si(CH₃)₂(CH₂)ₘ—), polysiloxanes of enhanced crystallizability through modifications of chemical and stereochemical structures, elastomers from water-based emulsions, random and block copolymers, and blends thereof. The inorganic polymer coating may also be conducted via chemical vapor deposition (e.g., ALD, etc.), physical vapor deposition (e.g., plasma, ion plating, cathodic arc, sputtering, vacuum, etc.), chemical and electrochemical processes (e.g., electroplating), spraying, spin-coating, dip coating, lithographic coating, or a combination thereof.

In step 260 of process 200, the deposited inorganic polymer layer is dried. The drying may be conducted by independently choosing a temperature and time as defined above for step 230. The drying step of step 260 may be the same as or different from drying step 230. In some examples, the drying is conducted at a temperature of about 120° C. for a duration of about 30 seconds. In some examples, the drying is conducted at a temperature of about 150° C. for a duration of about 30 seconds.

Steps 270 and 280 exemplify curing steps of the inorganic polymer layer. In some examples, the curing may comprise only exposing the inorganic polymer layer to radiation to form a porous light extraction layer stack (i.e., only step 270). In some examples, the curing may comprise only thermally sintering the inorganic polymer layer to form a porous light extraction layer stack (i.e., only step 280). In some examples, the curing may comprise conducting steps 270 and 280 in series (i.e., step 270 followed by step 280, or vice-versa). In some examples, the curing may comprise conducting steps 270 and 280 in parallel (i.e., steps 270 and 280 together).

In some examples, step 270 is conducted as provided above for step 240. In some examples, curing step 270 may be the same as or different from step 240. For example, the inorganic polymer may be exposed to radiation having a peak emission wavelength in a range of 500 nm to 2000 nm or in a range of 750 nm to 1400 nm for a duration in a range of 1 second to 300 seconds, or 10 seconds to 120 seconds, or 10 seconds to 60 seconds (e.g., 45 seconds).

In some examples, step 280 is conducted at a temperature in a range of 100° C. to 350° C. (e.g., 300° C.) or in a range of 150° C. to 300° C. or in a range of 200° C. to 250° C. (e.g., 230° C.). In some examples, step 280 is conducted for a duration in a range of 1 minute to 10 minutes, or in a range of 3 minutes to 7 minutes, or in a range of 4 minutes to 6 minutes (e.g., 5 minutes). In some examples, step 280 is conducted at a temperature of about 230° C. for a duration of about 5 minutes. In some examples, step 280 is conducted at a temperature of about 300° C. for a duration of about 5 minutes.

In step 290 of process 200, OLED layers may be deposited on the porous light extraction layer stack. For example, the OLED layers can include a first electrode and a second electrode. The first electrode can be an anode and second electrode can be a cathode, or vice versa. In some examples, the first electrode may be transparent (e.g., ITO, etc.) while the second electrode may be transparent or reflective (e.g., gold (Au), silver (Ag), copper (Cu), or aluminum (Al)). An organic layer may be disposed between the first electrode and the second electrode. When a voltage is applied between the first electrode and the second electrode, the organic layer emits light. The organic layer can include a plurality of sub-layers, and a subset of those sub-layers may emit light.

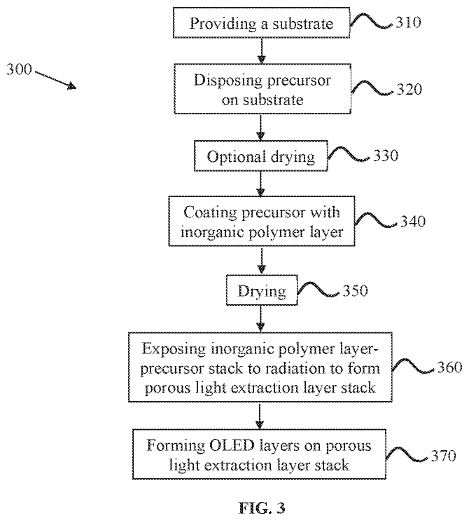

FIG. 3 illustrates a process 300 for NIR treatment, according to some embodiments whereby a substrate is provided (step 310) and a precursor is disposed atop the substrate (step 320), followed by an optional drying (step 330) similar to step 230 defined above. In some examples, step 330 is conducted prior to applying the inorganic polymer layer. In some examples, step 330 is not conducted prior to applying the inorganic polymer layer. Thereafter, the precursor is coated with the inorganic polymer in step 340 (similar to step 250), with the substrate-precursor-inorganic polymer stack undergoing drying in step 350 (similar to step 260).

In step 360 of process 300, the inorganic polymer layer-precursor stack may be exposed to radiation to form a porous light extraction layer stack whereby both the inorganic polymer layer and precursor layers are cured in a single processing step. For example, taking steps 340 to 360 together, the precursor is coated with the inorganic polymer prior to treating the combination with radiation. Step 360 is conducted in a similar manner as defined above for step 270. Finally, in step 370 of process 300, OLED layers may be deposited on the porous light extraction layer stack, analogously as explained in step 290.

### EXAMPLES

### Example 1

Process 200 and 300 and any examples disclosed herein may be modified such that a multiple-layer precursor is disposed on the substrate whereby the multiple-layer precursor comprises at least a first layer adjacent the substrate, the first layer comprising a first oxide and a first organic binder, and at least a second layer adjacent the first layer comprising a second oxide and a second organic binder. The first and second oxides may be the same or different and are at least one of an inorganic oxide, metal oxide, or metalloid oxide. The first and second organic binders may be the same or different.

### Example 2

Process 200 and 300 and any examples disclosed herein may be modified such that a multiple-layer inorganic polymer is disposed on the porous light extraction layer. In some implementations, the multiple-layer inorganic polymer comprises at least a first layer adjacent the porous light extraction layer, the first layer comprising a first siloxane-based polymer, and at least a second layer adjacent the first layer comprising a second siloxane-based polymer. The first and second siloxane-based polymers may be the same or different. In some implementations, the first layer may be disposed between the substrate and the porous light extraction layer (formed from the precursor) and the second layer may be disposed such that the porous light extraction layer is positioned between the first and second layers.

### Example 3

Process 200 and 300 and any examples disclosed herein may be modified such that the precursor and/or the inorganic polymer layer may be pretreated with drying and curing prior to assembly onto the substrate. For example, the precursor as described herein may be first disposed onto a dummy surface, dried, and then exposed to radiation to form a porous light extraction layer, with the formed porous light extraction layer then being transferred to the substrate. Likewise, the inorganic polymer may be first disposed onto a dummy surface, dried, and then exposed to radiation and/or thermally sintered. The treated inorganic polymer is then coated atop the porous light extraction layer (as in process 200) or the precursor (as in process 300).

### Example 4

Samples Preparation

Coating of the inorganic polymer (e.g., siloxane-based polymer) may be prepared by either a sheet type or a R2R slot-die coater.

### Example 5

NIR Experimental Setup

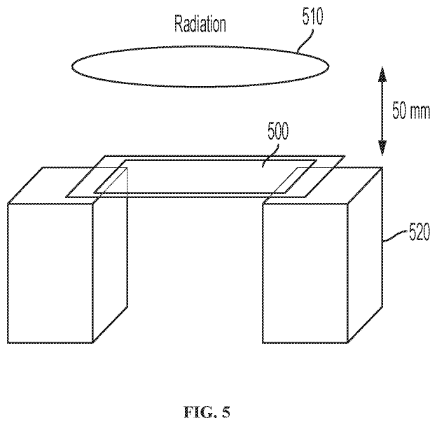

FIG. 5 illustrates a system for radiation treatment, according to some embodiments. As shown in FIG. 5, samples 500 were placed about 50 mm away from a radiation source 510 on a test stand 520 for treatment. Other distances between the flash lamp 510 and sample 500, for example between 20-100 mm, can be used. In some examples, the radiation is generated from a pulsed or steady-state radiation source comprising a metallic filament (e.g., at least one of a tungsten filament, a nickel-chromium (NiCr) filament, an iron-chromium-aluminum (FeCrAl) filament, or combinations thereof).

### Example 6

Precursor Exposure to NIR Radiation

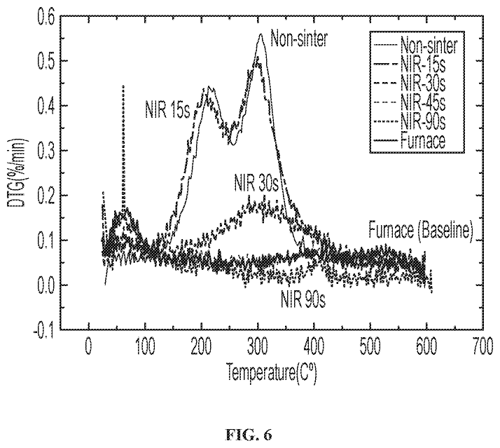

In some examples, a TiO₂-containing layer was used as a portion of the disposed precursor on the substrate. In such cases, the precursor was exposed to NIR radiation (100% power output) for processing times of 15 seconds, 30 seconds, 45 seconds, 60 seconds, and 90 seconds. The precursor samples exposed to radiation times of 30 seconds begin as yellowish color and then gradually turn white when the process time is longer than 45 seconds. Thermal gravimetric analysis (TGA) data of FIG. 6 confirms that samples having a NIR radiation exposure time of 45 seconds demonstrated comparable physical characteristics and properties as achieved with traditional thermal sintering (i.e., see Layer 2 sintering conditions of Table 1: 200° C. for 30 min).

### Example 7

Stack Layer Process Development and Characterization

To develop the NIR process for the planarization layer (i.e., as in, for example, process 300), a stack was prepared comprising TiO₂ treated with a standard thermal process (e.g., as in Table 1) followed by a planarization layer deposition and drying. In examples where the planarization layer was a polysiloxane-based material, hardness increased after irradiation and is comparable with sintering at 230° C. and 5 min in a furnace (see Layer 3 sintering conditions of Table 1). These results are show in Table 2. Control samples are sample not treated with either the NIR radiation or the traditional thermal sintering.

TABLE 2

| | | | | Furnace | |
|---|---|---|---|---|---|
| Laser | Exposure | | | Thermal | |
| Power | Time | Hardness | Discol- | Sintering | Control |
| (%) | (sec) | (GPa) | oration? | (GPa) | (GPa) |
| 100 | 15 | Surface | No | S: 0.65 | S: 0.56 |
| | | (S): 0.61 | | F: 0.31 | F: 0.27 |
| | | Film | | | |
| | | (F): 0.29 | | | |
| | 30 | S: 0.64 | Yes | | |
| | | F: 0.30 | | | |
| | 45 | S: 0.66 | Yes | | |
| | | F: 0.30 | | | |
| 80 | 30 | S: 0.63 | No | | |
| | | F: 0.29 | | | |
| | 45 | S: 0.62 | Yes | | |
| | | F: 0.29 | | | |
| | 60 | S: 0.72 | Yes | | |
| | | F: 0.33 | | | |
| 60 | 30 | S: 0.56 | No | | |
| | | F: 0.26 | | | |
| | 45 | S: 0.61 | No | | |
| | | F: 0.29 | | | |
| | 60 | S: 0.65 | No | | |
| | | F: 0.30 | | | |
| | 75 | S: 0.69 | Yes | | |
| | | F: 0.31 | | | |

Table 2 illustrates about a 20% hardness increase between the control samples and those exposed to at least a furnace thermal sintering. To achieve comparable results as the furnace treatment three separate laser powers were used at different time to optimize hardness data. For example, when using a laser power of 100%, exposure times varied between 15 seconds and 45 seconds. Roughly equivalent hardnesses were observed for the radiation- and furnace-treated samples for both the surface and film after an exposure time of 30 seconds. Visually, however, due to the laser power, the radiation samples experiencing a 30 second or 45 second exposure time turn brownish, which may impact overall lighting performance. With a 15 second processing time, while there is no significant change in sample color, surface and film hardness does not reflect equivalent value as the furnace treatment.

Thereafter, the laser power was reduced to 80% and further to 60% for process optimization (i.e., to achieve approximate hardness equivalence as the furnace-treated samples, while negating significant discoloration). At lower power outputs, similar phenomena are observed in that samples discolor to a yellowish or brownish tinge with increased processing time. For example, at a 60% power output for 60 seconds, the testing sample has similar hardness as a thermally sintered sample while still minimizing the degree of yellowish color.

Thus, the present disclosure relates to processes for making light extraction substrates for an organic light emitting diode (OLED) and products including such light extraction substrates. More specifically, the present application discloses improved processing conditions using near infrared radiation (NTR) for forming internal light extraction layers that reduce thermal treatment temperatures and time requirements during the curing stage. For example, using near infrared processing, curing times are reduced for the precursor to less than or equal to 1 minute. The resulting light extraction article greatly reduces the processing time, manufacturing cost (e.g., low power consumption), and produces highly uniform and reliable articles. Moreover, the irradiation method also allows for flexibility on energy setting and power output.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

As utilized herein, “optional,” “optionally,” or the like are intended to mean that the subsequently described event or circumstance can or cannot occur, and that the description includes instances where the event or circumstance occurs and instances where it does not occur. The indefinite article “a” or “an” and its corresponding definite article “the” as used herein means at least one, or one or more, unless specified otherwise.

References herein to the positions of elements (e.g., “top,” “bottom,” “above,” “below,” etc.) are merely used to describe the orientation of various elements in the FIGURES. It should be noted that the orientation of various elements may differ according to other exemplary embodiments, and that such variations are intended to be encompassed by the present disclosure.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be apparent to those skilled in the art that various modifications and variations can be made without departing from the spirit or scope of the claimed subject matter. Accordingly, the claimed subject matter is not to be restricted except in light of the attached claims and their equivalents.

What is claimed is:

1. A process for forming an article for improved light extraction, the process comprising:
providing a base substrate;
disposing a precursor on the base substrate, the precursor comprising:
particles having an average diameter in a range of 10 nm to 1 μm and comprising an inorganic oxide and an organic binder;
exposing the precursor to a first radiation having a peak emission wavelength in a range of 500 nm to 2000 nm for a time in a range of 1 second to 300 seconds to form a porous light extraction layer having an average pore diameter in a range of 10 nm to 1000 nm,
wherein the porous light extraction layer improves light output of the article by a factor of 1.7× or greater.

2. The process of claim 1, wherein the step of exposing is for a time in a range of 10 seconds to 60 seconds.

3. The process of claim 1, wherein the inorganic oxide comprises a first inorganic material of titanium dioxide (TiO₂) and a second inorganic material including at least one of silicon dioxide (SiO₂), zinc oxide (ZnO), tin dioxide (SnO₂), or combinations thereof.

4. The process of claim 1, wherein the inorganic oxide comprises titanium dioxide (TiO₂).

5. The process of claim 1, wherein the organic binder comprises at least one of polyethylene glycol, polyethylene oxide, polyvinyl alcohol, polyvinylpyrrolidone, polyacryclic acid, or combinations thereof.

6. The process of claim 1, wherein the first radiation has a power in a range of 0.1 W/cm² to 1000 W/cm².

7. The process of claim 1, wherein the first radiation is operated at a power output of less than 100%.

8. The process of claim 1, wherein the first radiation is generated from a pulsed or steady-state radiation source comprising a metallic filament, wherein the metallic filament comprises at least one of a tungsten filament, a nickel-chromium (NiCr) filament, an iron-chromium-aluminum (FeCrAl) filament, or a combination thereof.

9. The process of claim 1, further comprising:
coating the porous light extraction layer with an inorganic polymer layer.

10. The process of claim 9, further comprising:
exposing the inorganic polymer layer to a second radiation to form a porous light extraction layer stack.

11. The process of claim 10, wherein the step of exposing the inorganic polymer layer comprises the second radiation having a peak emission wavelength in a range of 500 nm to 2000 nm for a time in a range of 1 second to 300 seconds.

12. The process of claim 11, wherein the step of exposing the inorganic polymer layer is for a time in a range of 10 seconds to 60 seconds.

13. The process of claim 9, further comprising:
thermally sintering the inorganic polymer layer to form a porous light extraction layer stack.

14. The process of claim 9, wherein the inorganic polymer layer comprises siloxane-based molecules.

15. The process of claim 9, wherein the inorganic polymer is a planarizing layer on the porous light extraction layer.

16. The process of claim 9, wherein the inorganic polymer layer is a thickness in a range of 0.01 μm to 1 μm.

17. The process of claim 1, wherein the base substrate comprises a continuous, flexible sheet, and the process comprises a roll-to-roll process.

18. The process of claim 17, wherein the continuous, flexible sheet comprises a glass sheet with a thickness of 100 μm or less.

19. The process of claim 1, wherein a maximum temperature of the porous light extraction layer during the step of exposing is 250° C. or less.

20. The process of claim 1, further comprising:
forming at least one transparent electrode layer and an organic light emitting diode layer on the porous light extraction layer stack.

21.-27. (canceled)
